(19) United States
(12) Patent Application Publication
(10) Pub. No.: US 2026/0089876 A1
(43) Pub. Date: Mar. 26, 2026

(54) Fan Control Setting Generation Using Machine Learning

(71) Applicant: NetApp, Inc., San Jose, CA (US)

(72) Inventors: Ravi Kumar Choubey, Bangalore (IN); Kalpesh Goyal, Indragarh (IN); Parthiban D P, Bangalore (IN); Maheswari A, Krishnagiri (IN)

(73) Assignee: NetApp, Inc., San Jose, CA (US)

(21) Appl. No.: 18/897,885

(22) Filed: Sep. 26, 2024

(51) Int. Cl. H05K 7/20; G06N 20/00

(52) U.S. Cl. CPC H05K 7/20209; G06N 20/00

(57) ABSTRACT

The disclosure describes system, devices, and methods for fan speed control. In an example implementation, a method for operating a computer-implemented service is provided. The method includes obtaining sensor data from one or more sensors in a data storage environment. The sensor data includes temperature data associated with storage devices in the data storage environment. The method also includes providing an input (e.g., the sensor data) to a machine learning model trained to predict fan control settings of a fan in the data storage environment, determining the fan control setting based on an output from the machine learning model, and controlling the fan based on the fan control setting.

### TECHNICAL FIELD

Embodiments of the present disclosure relate generally to fan-speed control, and in particular, to controlling speeds of fans in data storage contexts.

### BACKGROUND

Fans are commonly used to cool power and computing hardware to prevent overheating and damage to such devices. In the context of data centers and data storage enterprise environments, baseboard management controllers (BMCs) are often used to monitor physical states of servers and storage devices and control fans to maintain the health and condition of the servers and storage devices.

During operation of the servers, such as when managing data of the storage devices, a BMC retrieves health parameters from sensors of components in the environment and regulates speeds of the fans used to cool the servers and storage devices based on the health parameters. Accordingly, the BMC increases the speed of a fan upon an increase in device temperature, and the BMC decreases the speed of the fan if the device temperature is sufficiently reduced over the course of operation.

Typically, the BMC increases or decreases fan speeds in fixed increments. For example, the BMC increases the fan speed from 50% to 65% after identifying an increase in temperature beyond a threshold. Problematically, such incremental increases in fan speed may consume more power than is needed as a smaller increase might have sufficed to reduce server temperature. On the other hand, however, BMCs typically cannot change the fan speed in small increments because the change in fan speed might not decrease the temperature adequately, or quickly enough, to prevent overheating and damage caused thereby. Thus, existing fan controllers often waste power creating inefficiencies in data storage environments.

### SUMMARY

The technology described herein includes system controller that determines precise fan control settings with which to control fans in a data storage environment thereby increasing power savings while also reducing risk of overheating and damage to components of the data storage environment. While generally applicable to numerous endeavors, such advantages may be especially useful in the context of data storage environments, data management and processing environments, and other computing environments.

In an implementation, a system controller for controlling fan speeds is provided. The system controller includes a processing device capable of executing a machine learning model trained to predict fan control settings based on system states (e.g., temperature, processing load, power savings, risk factors, component type).

During training, the machine learning model is fed test system states as input and determines a fan control setting based on the input. The fan control setting is implemented to determine whether the fan sufficiently reduces temperature(s) of the data storage environment beyond a threshold amount and for a threshold duration. The fan control setting is iteratively and sequentially decremented in this way until the fan no longer reduces the temperature(s) beyond the threshold amount and/or for the threshold duration. A minimum fan control setting is thus determined based on the fan control setting satisfying the minimum cooling conditions and is correlated with the test system states. Several combinations and variations of test system states may be fed to the machine learning model to train the model to predict fan control settings at run-time.

During run-time (also referred to as inferencing), the system controller provides real-time system states to the machine learning model to identify precise fan control settings based on the real-time system states and using the trained data. Based on the output from the machine learning model, the system controller controls operation of the fans in the data storage environment to cool the data storage environment, and components thereof, with efficiency and effectiveness with respect to power savings and temperature reduction.

This Overview is provided to introduce a selection of concepts in a simplified form that are further described below in the Technical Disclosure. It may be understood that this Overview is not intended to identify key features or essential features of the claimed subject matter, nor is it intended to be used to limit the scope of the claimed subject matter.

### BRIEF DESCRIPTION OF THE DRAWINGS

For a more complete understanding of the present invention(s), and the advantages thereof, reference is now made to the following descriptions taken in conjunction with the accompanying drawings.

FIG. 1 illustrates an operating environment in an implementation.

FIG. 2 illustrates an operational method in an implementation.

FIG. 3 illustrates a training method in an implementation.

FIG. 4 illustrates an operating environment in an implementation.

FIG. 5 illustrates an example machine learning model in an implementation.

FIG. 6 illustrates an operational scenario related to training a machine learning model in an implementation.

FIG. 7 illustrates example tables including sample parameters and fan control settings in an implementation.

FIG. 8 illustrates an operating environment in an implementation.

FIG. 9 illustrates an operating environment in an implementation.

FIG. 10 illustrates a computing system suitable for implementing the various operational environments, architectures, environments, methods, processes, scenarios, sequences, and frameworks discussed below with respect to the other Figures.

Corresponding numerals and symbols in different figures generally refer to corresponding parts unless otherwise indicated. The figures are drawn to clearly illustrate the relevant aspects of the preferred embodiments and are not necessarily drawn to scale.

### DETAILED DESCRIPTION

Technology is disclosed herein that mitigates the problems discussed above with respect to controlling fan operations to cool data storage and computing environments. In various embodiments, machine learning and artificial intelligence (AI) techniques are used to determine specific fan control settings as opposed to using sparse, fixed incremental fan control settings, thereby increasing power savings and cooling efficiency.

In an example embodiment, a regression model is used to analyze and predict exact fan control settings based on real-time system states of components of a data storage environment. The system states correspond to operational or physical states of components, such as processing loads, processing capacities, temperatures, voltages, types, and the like. Examples of the components include processing devices (e.g. CPUs), batteries, storage devices (e.g., SSDs, HDDs), interface devices (e.g., input/outputs (I/Os), and the like. In operation, the regression model uses inputs indicative of the states of such components to determine fan control settings to cool the components to reduce risk of overheating while maximizing power savings.

Unlike existing fan controllers, a system controller employing machine learning and AI models controls speeds of fans in the data storage environment with precision and accuracy without over-consuming power. Conventionally, a baseboard management controller (BMC) of a computing environment regulates a fan’s PWM duty cycle on the basis of temperatures of different hardware components. However, the BMC might only be configured to set the PWM duty cycle of the fan to a limited number of fixed values. For example, the BMC may control the PWM duty cycle in step indexes including five increments from 35% to 50%, 50% to 65%, 65% to 80%, and 80% to 100%. When any hardware component breaches a temperature threshold, the BMC increases the fan step indexes one by one. If the BMC controls the fan to operate at 35%, the fan PWM duty cycle will be increased to 50% and maintained there for a minute. If this does not help in reducing the temperature below the fan trip threshold, the fan PWM duty cycle will be moved to the subsequent step index 3 and so on.

Similarly, when all the hardware components have a temperature value less than the fan trip threshold, the BMC decreases the fan step indexes one by one. For example, if the BMC currently controls the fan to operate at 100% speed, the fan PWM duty cycle will be decreased to 80% for at least a minute. If the temperatures of all the hardware components remain below the fan trip thresholds, the BMC will continue to decrease the PWM duty cycle to the next step index and so on.

This incremental stepping up and down of the fan speeds leads to a significant increase in the power consumption. For example, consider a scenario where the fans are running at 65% PWM duty cycle, and the temperature of some hardware component increases. The BMC can control the fan to increase to 80% PWM duty cycle to reduce the temperature of the hardware components. However, in a practical scenario, it may be possible that an intermediate PWM Duty cycle, such as 67%, would have been sufficient to handle the temperature of the hardware component. The conventional BMC fails to identify or implement an optimal intermediate PWM duty cycle since it is configured to vary the duty cycles according to a fixed jump-state algorithm.

Instead, as disclosed herein, a system controller utilizing machine learning and AI techniques can predict exact fan PWM duty cycles required for specific temperature values of different hardware components. The model employed by the system controller may run periodically (e.g., every five seconds) and predict precise PWM duty cycles required for a number of fans. In a test scenario employing such techniques, power supply unit (PSU) power consumption decreased 80 Watts when the system controller operated a corresponding fan at 71% speed (based on prediction techniques) instead of 80% (using conventional incremental techniques).

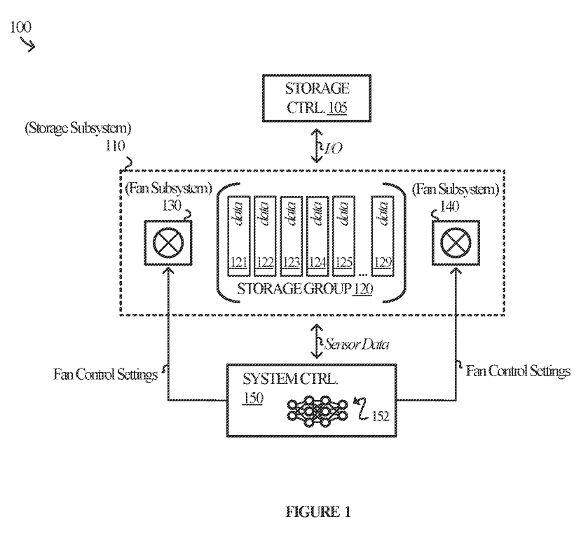

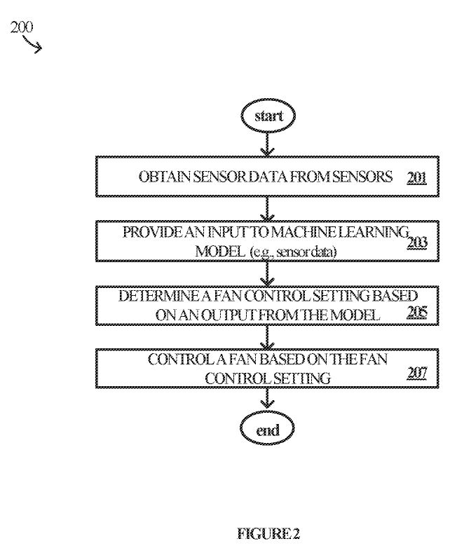

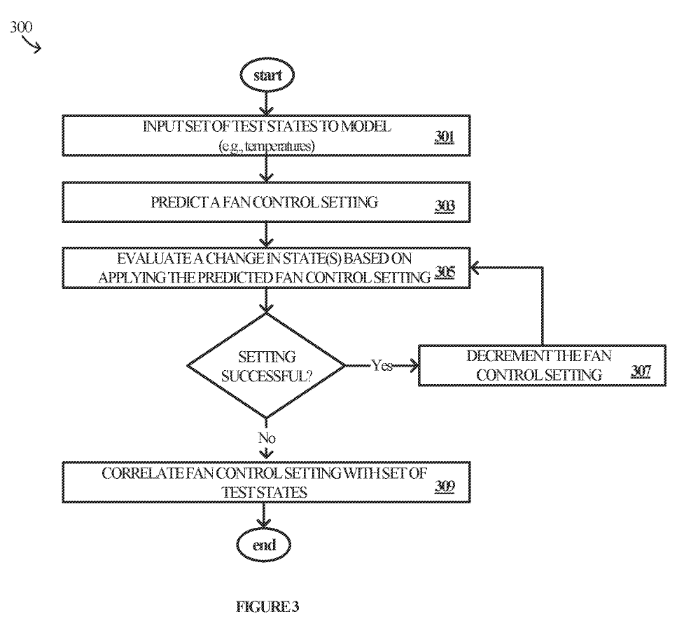

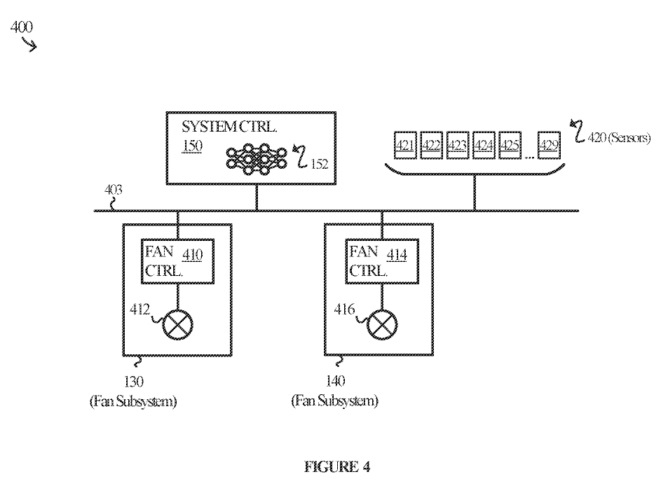

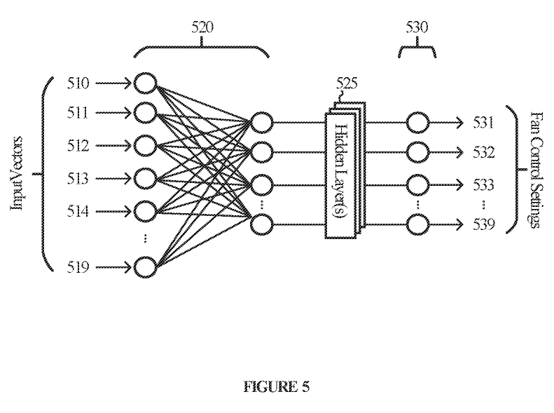

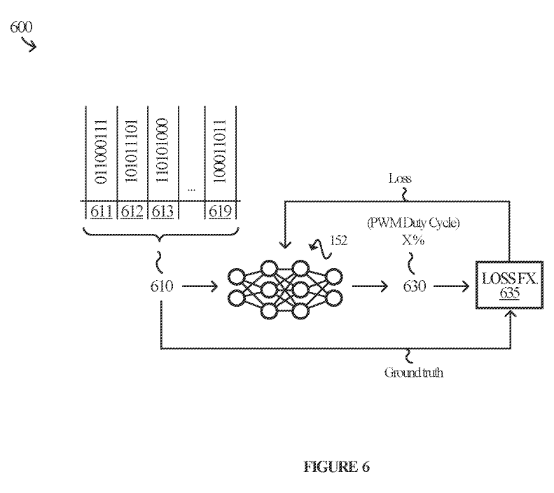

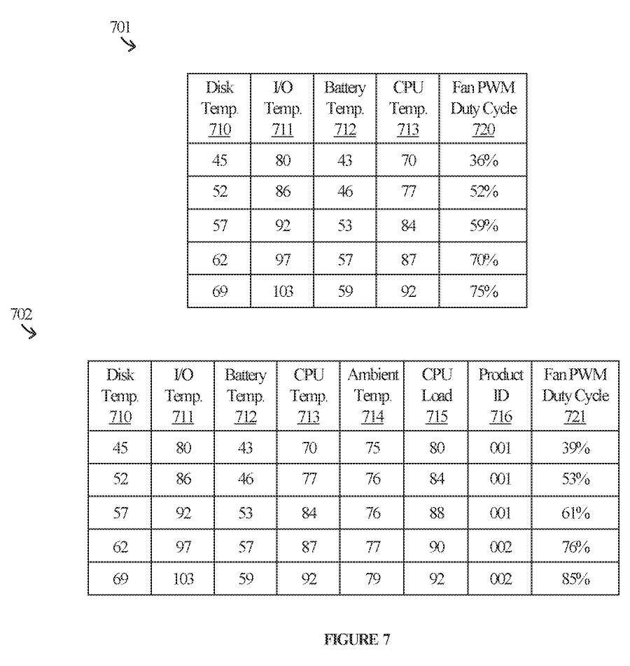

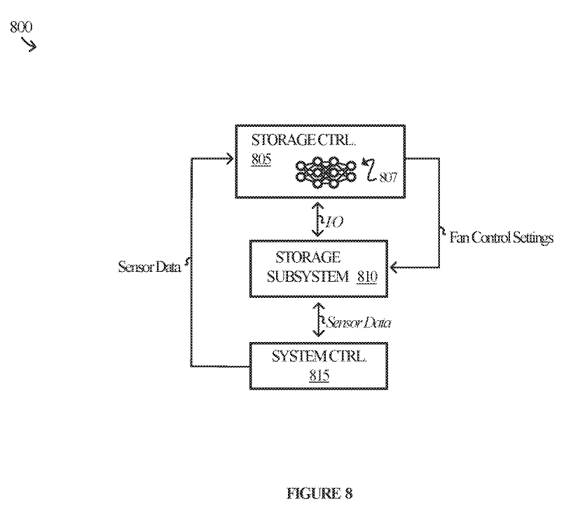

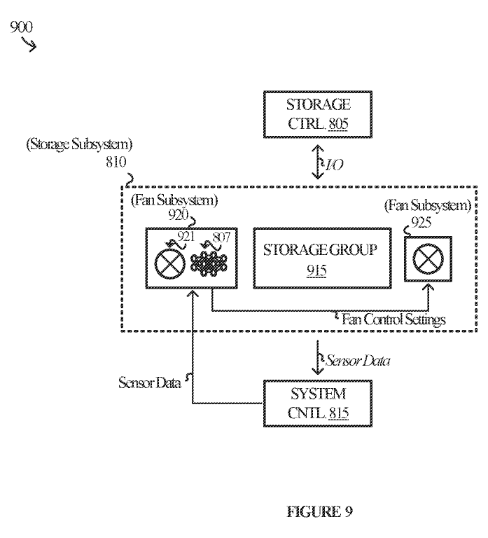

Turning now to the drawings, an implementation of a representative data storage environment is illustrated in FIG. 1, while inference and training methods are disclosed in FIGS. 2 and 3, respectively. FIG. 4 illustrates an operational environment in which a fan controller illustrated in FIG. 1 operates. FIG. 5 illustrates an example machine learning model trained to predict fan control settings of fans of the data storage environment of FIG. 1, while FIG. 6 illustrates an operational scenario for training the machine learning model of FIG. 5. FIG. 7 illustrates example input data fed to a machine learning model as well as output predictions produced by the machine learning model. FIGS. 8 and 9 illustrate alternative operational environments in which a fan controller may operate.

With respect to FIG. 1, operating environment 100 is illustrated, which includes storage controller 105, storage subsystem 110, and system controller 150. Storage subsystem 110 includes storage group 120, fan subsystem 130, and fan subsystem 140. System controller 150 includes model 152.

Storage controller 105 is representative of a computing device capable of hosting an application suitable for interface with a storage service. Storage controller 105 interfaces with client devices (e.g., server computers, personal computers, tablets, laptops, smartphones) via the application to provide access to the storage service. Example applications hosted on the client devices and storage controller 105 include, but are not limited to, productivity applications, database applications, gaming business applications, and the like. The applications running on the client devices send input/output (I/O) requests to storage controller 105. Storage controller 105 uses the I/O requests to write data to storage subsystem 110 and/or read data from storage subsystem 110 and provide information back to the client devices.

Storage subsystem 110 is representative of a storage service capable of managing data in storage group 120. Storage group 120 includes various storage devices, such as disks 121, 122, 123, 124, 125, and 129. Examples of the disks include, but are not limited to, solid state drives (SSDs), hard disk drives (HDDs), as well as other types of memory and storage devices. Storage group 120 may be representative of a physical rack or shelf of data and parity disks located in a data storage environment. Storage group 120 may also include power management components (e.g., batteries, power management units), interface components (e.g., I/O devices), processing components (e.g., disk controllers), sensors, and the like coupled to storage group 120 and capable of driving operations of the storage service.

Fan subsystems 130 and 140 are included in storage subsystem 110 to cool such elements of storage subsystem 110 to prevent overheating and damage caused thereby. Fan subsystems 130 and 140 each include one or more fans and one or more fan controllers coupled to a respective fan. In some examples, fan subsystems 130 and 140 include multiple fans, each fan positioned to cool a group of elements of storage subsystem 110.

System controller 150 is representative of a computing device capable of hosting model 152 suitable for controlling fan subsystems 130 and 140 of storage subsystem 110. Examples of the computing device include, but are not limited to, one or more central processing units (CPUs), general purpose processors, field-programmable gate arrays (FPGAs), digital signal processors (DSPs), application-specific integrated circuits (ASICs), and the like. Examples of model 152 include, but are not limited to, a convolution neural network, a deep-learning model, a regression model, and the like, as well as combinations and variations thereof.

System controller 150 interfaces with storage subsystem 110 to obtain sensor data indicative of states of components in storage subsystem 110. System controller 150 feeds the sensor data as input to model 152, which is trained to predict fan control settings based on inputs. System controller 150 then outputs fan control settings to fan subsystems 130 and 140 for control of respective fans to cool elements of storage subsystem 110. FIG. 2 illustrates a run-time, or inference, method 200 employed by model 152 to generate the fan control settings, while FIG. 3 illustrates a training method 300 employed by system controller 150 to train model 152.

Referring to FIG. 2, inference method 200 may be implemented in program instructions in the context of software and/or firmware elements of a computing system or device, such as a controller (e.g., system controller 150). The program instructions, when executed by one or more processing devices of one or more computing systems, direct the one or more computing systems to operate as follows, referring parenthetically to the steps in FIG. 2, and in the singular to a computing device for the sake of clarity.

To begin, the computing device receives (201) sensor data from sensors coupled to components operating in a data storage environment. Examples of the components coupled to the sensors include, but are not limited to, storage devices (e.g., disks of storage group 120), batteries, power supplies, processing devices, and the like. The sensor data includes sensed or measured values (also referred to as states) corresponding to such components related to temperature, load, load percentage, current, voltage, component type, and more. One or more sensors may also be included to measure ambient temperature at one or more different locations of the data storage environment.

Next, the computing device provides (203) the sensor data as an input to a machine learning model (e.g., model 152) trained to predict fan control settings based on inputs. This entails vectorizing each of the sensed states to generate feature embeddings or vectors and supplying the feature embeddings to an input of the model. In doing so, the computing device can supply multi-dimensional features characterizing the system states to the model.

The computing device determines (205) a fan control setting based on a predicted output from the machine learning model. The fan control setting may indicate a speed for one or more fans in the data storage environment (e.g., fans of fan subsystems 130 and/or 140). The speed may correspond to a pulse-width modulation (PWM) duty cycle at which to set the one or more fans (e.g., 55%) to reduce the temperature of the data storage environment and components thereof (e.g., disks of storage group 120).

Upon determining the fan control setting, the computing device controls (207) a fan based on the fan control setting. In particular, this may entail providing an indication of the fan control setting to a fan controller (e.g., a controller coupled to a fan in fan subsystem 130 and/or fan subsystem 140).

In some example embodiments, the machine learning model may predict multiple fan control settings for multiple fans in parallel, or sequentially. Further, the computing device may periodically obtain the sensor data over a duration, identify changes in the sensor data exceeding thresholds (e.g., a temperature increasing by a threshold amount), and provide the sensor data as input to the machine learning model based on identifying such changes. As such, the computing device can control fan operations using precise fan control settings to effectuate a reduction in temperature of a component at specific times without consuming more power than is needed relative to conventional solutions that utilize rigid fan speed increments resulting in excessive fan speeds, and thus power, in some situations.

The machine learning model employed by the computing device is operable in such ways based on being trained using training data that captures a variety of system states and corresponding fan control settings. Training of the machine learning model is described in training method 300 of FIG. 3.

In FIG. 3, training method 300 includes steps related to generating training data and training a machine learning model (e.g., model 152) using the training data. Training method 300 may be implemented in program instructions in the context of software and/or firmware elements of a computing system or device, such as a controller (e.g., system controller 150). The program instructions, when executed by one or more processing devices of one or more computing systems, direct the one or more computing systems to operate as follows, referring parenthetically to the steps in FIG. 3, and in the singular to a computing device for the sake of clarity.

To begin, the computing device inputs (301) a set of test states to the machine learning model. The test states refer to states of components of the data storage environment. In various examples, the test states include indications of temperature of storage devices in the data storage environment. The test states may additionally include indications of ambient temperature, processing load of processing devices, voltage or current of power management devices, temperature of processing devices, temperature of power management devices, and the like. In some instances, the test states include real-time measurements, while in some instances, the test states include simulated measurements.

Next, the computing device uses the machine learning model to predict (303) a fan control setting. During training, the machine learning model may predict an initial fan control setting corresponding to a maximum speed of a fan (e.g., 100% PWM duty cycle). The computing device then evaluates (305) a change in state(s) of the components in the data storage environment based on applying the predicted fan control setting to the fan. This entails controlling the fan using the predicted fan control setting and determining whether the states of the components (e.g., temperature) fall below a threshold amount. In particular, the threshold amount corresponds to a temperature at which the component operates without overheating and being damaged. As such, if the states fall below a threshold amount, the predicted fan setting is capable of effectuating an amount of change sufficient to prevent overheating and damage of the components. The threshold amount may vary by component.

Upon determining that the temperature of the components reduced below respective threshold amounts, the predicted fan control setting is deemed successful. For each successful fan control setting, the computing device decrements (307) the fan control setting by an amount (e.g., by 1%) and iteratively evaluates (305) a change in states based on the decremented fan control setting (e.g., now 99% PWM duty cycle).

Eventually, after decrementing the fan control setting a number of times, the computing device determines that a fan setting fails to reduce one or more of the states below a respective threshold amount. In other words, the temperature of at least one of the components does not reduce below a threshold amount, and as such, the component is at risk of damage. Based on determining a failed fan control setting, the computing device correlates (309) a successful fan control setting with the set of input test states.

In some examples, the computing device determines the successful fan control setting to be the most recent successful fan control setting predicted by the machine learning model immediately prior to the failed fan control setting (e.g., the failed fan control setting plus 1%).

In some examples, the computing device determines the successful fan control setting to be one of the successful fan control settings determined prior to the failed fan control setting. The one selected among the successful fan control settings may be based on a risk threshold and/or a power savings threshold. The risk threshold corresponds to a risk of the state increasing beyond the threshold amount within a threshold amount of time (e.g., 60 seconds). In other words, this refers to the risk of having to increase the fan speed within an amount of time after setting the fan speed to the selected fan control setting. The power savings threshold corresponds to an amount of power savings achieved using the selected successful fan control setting relative to the fan control setting predicted immediately prior to the failed fan control setting. By using such threshold parameters, the computing device determines and utilizes a fan control setting that optimizes risk and power savings while sufficiently cooling components of the data storage environment.

FIG. 4 illustrates an operating environment 400 in which system controller 150 interfaces with elements of a data storage environment to control fan operations in accordance with the inference method of FIG. 2. Operating environment 400 includes system controller 150, fan subsystem 130, fan subsystem 140, and sensors 420 in communication via interface 403.

As shown in operating environment 400, fan subsystem 130 includes fan controller 410 and fan 412, and fan subsystem 140 include fan controller 414 and fan 416. Fan controllers 410 and 414 are representative of computing devices (e.g., CPUs) capable of interfacing with system controller 150 via network 403 to receive fan control settings and interfacing with fans 412 and 416, respectively, to control respective fans therewith. Fans 412 and 416 are operable at varying speeds based on fan control settings provided by fan controller 410. Fans 412 and 416 are physically located nearby components in a data storage environment, such as storage devices (e.g., disks of storage group 120), to reduce temperatures of the components.

Sensors 420 includes sensors 421, 422, 423, 424, 425, and 429, each of which represents a type of sensor capable of sensing states of coupled components in the data storage environment. For example, sensors 420 includes a number of temperature sensors, voltage sensors, current sensors, load sensors, and the like. Sensors 420 are further coupled to system controller 150 via network 403.

Network 403 is representative of an interface or communication network over which system controller 150 obtains state information from sensors 420 and provides fan control settings to fan subsystem 130 and 140. In an example, network 403 is a physical connection between the elements, such as an inter-integrated circuit (I²C) interface. Other types of physical or virtual connections may be contemplated using a communication protocol.

FIG. 5 illustrates exemplary aspects of model 152 used to predict fan control settings. In FIG. 5, model 152 includes input layer 520, hidden layer(s) 525, and output layer 530.

Input layer 520 is representative of a layer of model 152 (e.g., a regression model) capable of interfacing with a computing device (e.g., system controller 150) to receive input vectors 510, 511, 512, 513, 514, and 519. The input vectors each represent features (independent variables) having multiple dimensions. Examples of the data submitted as the input vectors includes, but is not limited to, temperature states, processing load states, voltage states, power savings states, risk states, and the like. Input layer 520 provides the input vectors to hidden layer(s) 525.

Hidden layer(s) 525 is representative of one or more hidden layers of model 152 configured to apply activation functions on the input vectors. Examples of activation functions applied by hidden layers 525 includes Rectified Linear Unit (ReLU) functions, Sigmoid functions, Tanh functions, and the like. In some examples, one or more weighted sum layers may be included in model 152 in addition to or instead of hidden layers 525. Upon applying one or more activation functions on the input vectors, hidden layers 525 provide transformed vectors to output layer 530.

Output layer 530 is representative of a layer of model 152 capable of interfacing with the computing device to output fan control settings 531, 532, 533, and 539 to the computing device. Each fan control setting may include a specific fan parameter (e.g., fan PWM duty cycle) corresponding to one or more fans of the data storage environment. In the example illustrated in FIG. 5, model 152 is configured to ingest several input vectors and predict at least four fan control settings based on the input vectors. Other examples may include any number of input vectors and output fan control settings.

An example operational scenario related to the training of model 152 is shown in FIG. 6. FIG. 6 includes training scenario 600, which may be carried out by elements of a system controller, such as system controller 150 of FIG. 1. As such, training scenario 600 references elements of operating environment 100 of FIG. 1.

Training scenario 600 begins when system controller 150 supplies input 610 to model 152. Input 610 includes feature embeddings, 611, 612, 613, and 619, which represent input vectors including multi-dimensional features associated with system states. The values and dimensions of input 610 may include test/sample (e.g., simulated) system states, or they may include real-time, experimental states. By way of example, the experimental states may be obtained by manually heating components of a system.

The system states are indicative of operational values of components in storage subsystem 110, such as average temperature of storage group 120, temperature of each disk of storage group 120, temperature of processing devices coupled to the disks of storage group 120, ambient temperature surrounding storage group 120, processing loads of the processing devices, and the like.

Based on input 610, model 152 is configured to output a predicted fan control setting 630 corresponding to the input 610. The predicted fan control setting 630 represents a fan speed with which to reduce temperature(s) (e.g., system states) of components below a threshold amount for a threshold duration. In various examples, predicted fan control setting 630 includes a non-zero integer value, X, corresponding to a fan PWM duty cycle (e.g., 100%). The predicted fan control setting 630 is fed to loss function 635.

Loss function 635 is representative of a mathematical function that measures the difference between the predicted fan control setting 630 and a ground truth fan control setting (e.g., an actual target fan control setting) to iteratively train model 152. For example, loss function 635 calculates a loss amount and provides the loss to model 152 for model 152 to adjust model parameters (e.g., weights) to minimize future loss and improve predictions of fan control settings over time. Based on the amount of loss, the output of loss function 635 may indicate a pass or fail corresponding to whether the predicted fan control setting 630 reduces the temperature(s) of components below the threshold amount for the threshold duration.

Upon receiving the loss amount, model 152 updates weights and other parameters of layers of model 152 (e.g., hidden layers 525) and outputs a subsequent predicted fan control setting. Loss function 635 and model 152 iteratively repeat this process. In various examples, the process is repeated until the loss amount falls below a threshold loss amount indicating an accurate and correct predicted fan control setting for a given set of system states (input 610). Additionally, or instead, the process may be repeated until loss function 635 indicates a fail corresponding to a predicted fan control setting.

The entire process can be repeated for variations and combinations of system states until a satisfactory set of training data is generated for model 152 such that model 152 can predict fan control settings for a given set of system states with minimal loss (e.g., loss below the threshold loss amount) and without a failure with respect to reducing temperature.

In various examples, model 152 initially outputs predicted fan control setting 630 having a value of 100% for input 610. Based on loss function 635 indicating that 100% includes an amount of loss above a loss threshold and/or is a passing fan control setting, model 152 updates weights and parameters such that the following predicted fan control setting includes a value lower than 100%. In some such examples, subsequent predicted fan control settings have values decremented by 1% relative to the immediately previous predicted fan control setting. As such, the second predicted fan control setting has a value of 99% for input 610, the third predicted fan control setting has a value of 98% for input 610, and so on until model 152 determines the weights and parameters associated with input 610 resulting in a predicted fan control setting preceding a failed fan control setting (e.g., X + 1%) and with loss at or below the loss threshold.

FIG. 7 shows exemplary inputs and corresponding fan control settings representative of training data used to train model 152 in an implementation. FIG. 7 includes table 701 and table 702.

Referring first to table 701, table 701 includes example system state values associated with components in a data storage environment (e.g., operating environment 100). Such components may include storage devices (e.g., disks in storage group 120), power supply devices or power management units, processing devices (e.g., I/O devices, processing units), and the like. In table 701, the example system state values correspond to disk temperature 710, I/O temperature 711, battery temperature 712, and CPU temperature 713. Each of these system state values correspond to a temperature value of a particular device or group of devices in the data storage environment. In some examples, these values may correspond to a single device. In some examples, these values may be an average value corresponding to two or more devices.

For a first set of system states where disk temperature 710 includes a value of 45, I/O temperature 711 includes a value of 80, battery temperature 712 includes a value of 43, and CPU temperature includes a value of 70, model 152 outputs fan PWM duty cycle 720 (a predicted fan control setting) having a value of 36%. In various examples, 36% represents the lowest possible fan control setting to effectuate a reduction in temperature of each of the system states below a respective threshold value. In some examples, 36% represents a possible fan control setting to effectuate a reduction in temperature of each of the system states below a respective threshold value while also saving an amount of power above a threshold amount and reducing a risk of increasing the fan control setting within a threshold amount of time.

Table 701 includes other sets of system states related to disk temperature 710, I/O temperature 711, battery temperature 712, and CPU temperature 713 as well as associated fan PWM duty cycles 720 not mentioned for the sake of brevity.

Table 702 includes example system state values associated with additional components in a data storage environment (e.g., operating environment 100). Such components may include storage devices, power supply devices or power management units, processing devices, and the like. In table 702, the example system state values correspond to disk temperature 710, I/O temperature 711, battery temperature 712, CPU temperature 713, ambient temperature 714, CPU load 715, and product ID 716. CPU load 715 may include a percentage value indicative of a percentage of total processing capacity being used by one or more processing devices in the data storage environment. Product ID 716 may include an indicator indicative of a type of the system controller (e.g., system controller 150) implemented in the data storage environment capable of hosting model 152.

For a first set of system states where disk temperature 710 includes a value of 45, I/O temperature 711 includes a value of 80, battery temperature 712 includes a value of 43, CPU temperature includes a value of 70, ambient temperature 714 includes a value of 75, CPU load 715 includes a value of 80, and product ID 716 includes a value of 001, model 152 outputs fan PWM duty cycle 721 (a predicted fan control setting) having a value of 39%. Similar to above, 39% may represent the lowest possible fan control setting to effectuate a reduction in temperature of each of the system states below a respective threshold value. In some examples, 39% represents a possible fan control setting to effectuate a reduction in temperature of each of the system states below a respective threshold value while also saving an amount of power above a threshold amount and reducing a risk of increasing the fan control setting within a threshold amount of time.

Table 702 includes other sets of system states related to disk temperature 710, I/O temperature 711, battery temperature 712, CPU temperature 713, ambient temperature 714, CPU load 715, and product ID 716, as well as associated fan PWM duty cycles 721 not mentioned for the sake of brevity.

It may be appreciated that tables 701 and 702 include only a few exemplary combinations of system states and fan control settings. Several other combinations and variations thereof may be used to train model 152. Additionally, other system states associated with the same or different components may be contemplated.

FIGS. 8 and 9 include operating environments 800 and 900, respectively, representative of data storage environments in which machine learning and AI techniques may be used to control fan operations to cool elements of the data storage environments similar to operating environment 100 of FIG. 1. However, unlike operating environment 100, a machine learning model trained to predict fan control settings may be operable in different locations relative to operating environment 100. Elements of operating environments 800 and 900 may be configured to perform inference and training methods, such as methods 200 and 300 of FIGS. 2 and 3, respectively.

In FIG. 8, operating environment 800 includes storage controller 805, storage subsystem 810, and system controller 815. Storage controller 805 is representative of a computing device (e.g., storage controller 105) capable of hosting an application suitable for interface with a storage service. Storage controller 805 interfaces with client devices (e.g., server computers, personal computers, tablets, laptops, smartphones) via the application to provide access to the storage service. Example applications hosted on the client devices and storage controller 805 include, but are not limited to, productivity applications, database applications, gaming business applications, and the like. The applications running on the client devices send input/output (I/O) requests to storage controller 805. Storage controller 805 uses the I/O requests to write data to storage subsystem 810 and/or read data from storage subsystem 810 and provide information back to the client devices.

Storage subsystem 810 is representative of a storage service (e.g., storage subsystem 110) capable of managing data in various storage devices thereof (e.g., storage group 120). Storage subsystem 810 includes various storage devices (e.g., SSDs, HDDs), power management components (e.g., batteries, power management units), interface components (e.g., I/O devices), processing components (e.g., disk controllers), sensors, and the like. Storage subsystem 810 also includes cooling devices (e.g., fans) to reduce temperatures of elements of storage subsystem 810 to prevent overheating and damage caused thereby.

System controller 815 is representative of a computing device (e.g., system controller 150) capable of obtaining sensor data from elements of storage subsystem 810. More particularly, system controller 815 interfaces with storage subsystem 810 to obtain sensor data indicative of states of components in storage subsystem 810. System controller 815 feeds the sensor data as input to model 807, representative of a machine learning model (e.g., a regression model, e.g., model 152) hosted by storage controller 805, which is trained to predict fan control settings based on inputs. Storage controller 805 obtains outputs from model 807 and outputs fan control settings to storage subsystem 810 for control of fans thereof to cool elements of storage subsystem 810.

In another embodiment, such as one illustrated in operating environment 900 of FIG. 9, machine learning model 807 may be hosted instead by an element of a storage subsystem 810. Operating environment 900 includes storage controller 805, storage subsystem 810, and system controller 815, where storage subsystem 810 includes storage group 915, fan subsystem 920, and fan subsystem 925. Fan subsystem 920 further includes fan 921 and model 807.

In operation, system controller 815 obtains sensor data from elements of storage subsystem 810 and provides the sensor data to fan subsystem 920 as an input to model 807. Then, model 807 outputs fan control settings with which fan subsystem 920 uses to control operations of fan 921 and one or more fans of fan subsystem 925. Storage subsystem 810 may include additional fan subsystems and fans, which may be controlled by outputs of model 807. Additionally, operating environment 900 may include more fan subsystems, which may also be controlled by the outputs of model 807.

It may be appreciated from the discussion above that developing strategies to reduce power in data storage environments has become important for enterprises. As the number of data storage devices and fans to cool the data storage devices increases, the amount of power required to prevent overheating and damage to hardware components in the environments increases.

To mitigate power inefficiencies in fan speed control, a system is proposed herein for predicting precise fan control settings to save power instead of using rigid incrementing techniques that may be wasteful with respect to power usage. The system can train a machine learning model using training data obtained iteratively decrementing predicted fan control settings in a descending pattern from a maximum fan control setting to a fan control setting that achieves target cooling and power saving requirements. This machine learning model can ingest a set of system states (e.g., temperatures) from different components in the data storage environment and determine an exact fan control setting with which to control fans to effectuate cooling while also saving power. This reduces power consumption within the data storage environment, which may in turn reduce overall temperatures in the data storage environment and allow power usage elsewhere.

Various embodiments of the present technology provide for a wide range of technical effects, advantages, and/or improvements to computing systems and components. For example, various embodiments may include one or more of the following technical effects, advantages, and/or improvements: 1) fan power efficiency; 2) component temperature reduction efficiency; and/or 3) fan speed precision.

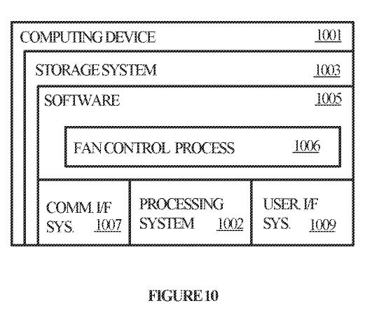

FIG. 10 illustrates computing system 1001, which is representative of any system or collection of systems in which the various applications, processes, services, and scenarios disclosed herein may be implemented. Examples of computing system 1001 include, but are not limited to server computers, web servers, cloud computing platforms, and data center equipment, as well as any other type of physical or virtual server machine, container, and any variation or combination thereof.

Computing system 1001 may be implemented as a single apparatus, system, or device or may be implemented in a distributed manner as multiple apparatuses, systems, or devices. Computing system 1001 includes, but is not limited to, processing system 1002, storage system 1003, software 1005, communication interface system 1007, and user interface system 1009. Processing system 1002 is operatively coupled with storage system 1003, communication interface system 1007, and user interface system 1009.

Processing system 1002 loads and executes software 1005 from storage system 1003. Software 1005 includes and implements fan control process 1006, which is representative of the processes discussed with respect to the preceding Figures, such as inference method 200 and training method 300, as well as operational scenarios and sequences, such as those in FIGS. 6. When executed by processing system 1002, software 1005 directs processing system 1002 to operate as described herein for at least the various processes, operational scenarios, and sequences discussed in the foregoing implementations. Computing system 1001 may optionally include additional devices, features, or functionality not discussed for purposes of brevity.

Referring still to FIG. 10, processing system 1002 may include a microprocessor and other circuitry that retrieves and executes software 1005 from storage system 1003. Processing system 1002 may be implemented within a single processing device but may also be distributed across multiple processing devices or sub-systems that cooperate in executing program instructions. Examples of processing system 1002 include general purpose central processing units, microcontroller units, graphical processing units, application specific processors, integrated circuits, application specific integrated circuits, and logic devices, as well as any other type of processing device, combinations, or variations thereof.

Storage system 1003 may comprise any computer readable storage media readable by processing system 1002 and capable of storing software 1005. Storage system 1003 may include volatile and nonvolatile, removable, and non-removable media implemented in any method or technology for storage of information, such as computer readable instructions, data structures, program modules, or other data. Examples of storage media include random access memory, read only memory, magnetic disks, optical disks, flash memory, virtual memory and non-virtual memory, magnetic cassettes, magnetic tape, magnetic disk storage or other magnetic storage devices, or any other suitable storage media. In no case is the computer readable storage media a propagated signal. Storage system 1003 may be implemented as a single storage device but may also be implemented across multiple storage devices or sub-systems co-located or distributed relative to each other. Storage system 1003 may comprise additional elements, such as a controller capable of communicating with processing system 1002 or possibly other systems.

Software 1005 (including fan control process 1006) may be implemented in program instructions and among other functions may, when executed by processing system 1002, direct processing system 1002 to operate as described with respect to the various operational scenarios, sequences, and processes illustrated herein. For example, software 1005 may include program instructions for implementing fan control setting determination and training, fan control setting training data generation, machine learning model training, and related processes and procedures as described herein.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

The included descriptions and figures depict specific embodiments to teach those skilled in the art how to make and use the best mode. For the purpose of teaching inventive principles, some conventional aspects have been simplified or omitted. Those skilled in the art will appreciate variations from these embodiments that fall within the scope of the disclosure. Those skilled in the art will also appreciate that the features described above may be combined in various ways to form multiple embodiments. As a result, the invention is not limited to the specific embodiments described above, but only by the claims and their equivalents.

What is claimed is:

1. A controller, comprising:
a sensor interface configured to couple to one or more sensors in a data storage environment;
a processing device configured to execute a machine learning model trained to predict fan control settings of fans in the data storage environment, wherein the machine learning model is trained based on training data comprising test states and corresponding fan control settings determined by iteratively changing the fan control settings for given test states until reaching threshold fan control settings for the given test states; and
a fan control interface configured to couple to the fans in the data storage environment;
wherein the sensor interface is configured to:
obtain sensor data from the one or more sensors, wherein the sensor data comprises temperature states associated with storage devices in the data storage environment; and
provide an input to the machine learning model, wherein the input comprises the sensor data;
wherein the processing device is configured to determine, via the machine learning model, a fan control setting of a fan in the data storage environment based on the input; and
wherein the fan control interface is configured to:
obtain the fan control setting from the processing device; and
control the fan based on the fan control setting.

2. The controller of claim 1, wherein the input further comprises a power savings state and a risk threshold state.

3. The controller of claim 1, wherein the temperature states comprises temperature values of the storage devices in the data storage environment, processing devices in the data storage environment, and power management units in the data storage environment.

4. The controller of claim 3, wherein the sensor data further comprises load states associated with the processing devices in the data storage environment, wherein the load states comprise indications of a given loads of processing devices relative to load capacities of the processing devices.

5. The controller of claim 3, wherein the sensor data further comprises an ambient temperature state of the data storage environment.

6. The controller of claim 1, wherein the fan control setting comprises a pulse-width modulation (PWM) duty cycle value with which to control a speed of the fan.

7. The controller of claim 1, wherein to obtain the sensor data from the one or more sensors in the data storage environment, the sensor interface is configured to obtain the sensor data from the one or more sensors via an inter-integrated circuit interface.

8. A computing apparatus comprising:
one or more computer-readable storage media; and
program instructions stored on the one or more computer-readable storage media executable by a processing device that, based on being read and executed by the processing device, direct the processing device to:
obtain sensor data from one or more sensors in a data storage environment, wherein the sensor data comprises temperature data associated with storage devices in the data storage environment;
provide an input to a machine learning model trained to predict fan control settings of a fan in the data storage environment, wherein the input comprises the sensor data;
determining a fan control setting based on an output from the machine learning mode; and
control the fan based on the fan control setting.

9. The computing apparatus of claim 8, wherein the temperature data comprises temperatures of the storage devices in the data storage environment, processing devices in the data storage environment, and power management units in the data storage environment.

10. The computing apparatus of claim 9, wherein the sensor data further comprises load data associated with the processing devices in the data storage environment.

11. The computing apparatus of claim 9, wherein the sensor data further comprises ambient temperature data of the data storage environment.

12. The computing apparatus of claim 8, wherein the fan control setting comprises a pulse-width modulation (PWM) duty cycle value with which to control a speed of the fan.

13. The computing apparatus of claim 9, wherein the input further comprises a power savings metric and a risk threshold metric, and wherein to determine the fan control setting of the fan, the machine learning model is configured to determine the fan control setting based on further on the power savings metric and the risk threshold metric.

14. The computing apparatus of claim 8, wherein to obtain the sensor data from the one or more sensors in the data storage environment, the sensor interface is configured to obtain the sensor data from the one or more sensors via an inter-integrated circuit interface.

15. A method, comprising:
obtaining sensor data from one or more sensors in a data storage environment, wherein the sensor data comprises temperature data associated with storage devices in the data storage environment;
providing an input to a machine learning model trained to predict fan control settings of a fan in the data storage environment, wherein the input comprises the sensor data;
determining the fan control setting based on an output from the machine learning model; and
controlling the fan based on the fan control setting.

16. The method of claim 15, wherein the temperature data comprises temperatures of the storage devices in the data storage environment, processing devices in the data storage environment, and power management units in the data storage environment.

17. The method of claim 16, wherein the sensor data further comprises load data associated with the processing devices in the data storage environment.

18. The method of claim 16, wherein the sensor data further comprises ambient temperature data of the data storage environment.

19. The method of claim 15, wherein the fan control setting comprises a pulse-width modulation (PWM) duty cycle value with which to control a speed of the fan.

20. The method of claim 16, wherein the input further comprises a power savings metric and a risk threshold metric, and wherein determining the fan control setting is further based on the power savings metric and the risk threshold metric.
